(19) United States
(12) Patent Application Publication
(10) Pub. No.: US 2007/0200585 A1
(43) Pub. Date: Aug. 30, 2007

(54) Semiconductor wafer, semiconductor chip, semiconductor device, and wafer testing method

(75) Inventors: Noboru Takeuchi, Tenri-shi (JP); Takahiro Inoue, Katsuragi-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/702,180

(22) Filed: Feb. 5, 2007

(30) Foreign Application Priority Data
Feb. 27, 2006 (JP) 2006-51121

(51) Int. Cl. G01R 31/02

(52) U.S. Cl. 324/763

(57) ABSTRACT

A semiconductor wafer of the present invention includes switch circuits each connecting a corresponding internal circuit formed in the semiconductor chip and the test pad. The semiconductor wafer also includes switch control pads which are provided in the scribing region or the semiconductor chips. Voltages of the switch control pads are pulled up or down to a voltage that is equal to a substrate voltage of the semiconductor wafer. The switch control pads are provided with signals whose voltages are different from the substrate voltage so that the switch circuits are turned on. Moreover, each of the test pads, which intervenes between the semiconductor chips adjacent to each other, is connected to at least one of said switch circuits of each of the adjacent semiconductor chips.

This Nonprovisional application claims priority under 35 U.S.C. § 119(a) on Patent Application No. 051121/2006 filed in Japan on Feb. 27, 2006, the entire contents of which are hereby incorporated by reference.

### FIELD OF THE INVENTION

The present invention relates to a semiconductor wafer, a semiconductor chip cut from the semiconductor wafer, a semiconductor device including the semiconductor chip, and a wafer testing method.

### BACKGROUND OF THE INVENTION

Generally, semiconductor integrated circuits (hereinafter, simply referred to as chips) are formed on a semiconductor wafer so as to be arranged and aligned lengthways and crosswise at predetermined pitches. After wafer test, the semiconductor wafer is diced into chips.

The wafer test is a process for checking whether each of the chips operates normally or not. Specifically, electric characteristics are tested for each of the chips by inputting/outputting electrical signals to/from test pads provided for the wafer test in each of the chips, while bringing a probe needle into contact with the test pads. This allows non-defective chips and defective chips to be sorted out among the chips. Then, only the non-defective chips are picked up after the dicing, and mounted on frames or substrates. Thereafter, each of the non-defective chips is packaged and sealed after processes such as wire bonding. Hereinafter, the process from chip-picking to packaging and sealing is referred to as an assembly process.

In recent years, progress in miniaturization technology has led to higher chip integration. This causes an increase in the number of test pads and, consequently, an increase in chip area. Ultimately, this increase in chip area causes a serious cost increase. Therefore, a semiconductor wafer having higher packaging density and a wafer testing method thereof are important.

Here, an example of a conventional semiconductor wafer and a conventional wafer testing method thereof, which satisfy the requirement mentioned above, is explained with reference to FIG. 14.

FIG. 14 briefly illustrates a configuration of chips (IC chips) 140 disclosed in Publicly Known Document 1 (Japanese Unexamined Patent Publication No. 50326/1995 (Tokukaihei 7-50326) (published on Feb. 21, 1995)). A scribing region S, in FIG. 14, is a reserved region for dicing on the semiconductor wafer 150 on which the chips 140 are formed. A dicing width Sd is a part to be removed by dicing. Moreover, a wire bonding pad (hereinafter, referred to simply as a bonding pad Bp) is a pad to be used in the assembly process. Furthermore, an internal circuit is a functional circuit formed in each of the chips 140.

As illustrated in FIG. 14, regarding each of the chips 140, a test pad 90 is formed in a scribing region S (a bonding pad Bp is formed in each chip). According to this arrangement, it is possible (i) to remove the test pad 90, which is necessary only during a wafer test, at dicing and (ii) to form a necessary pad (bonding pad Bp) only in each chip. Therefore, pads can be formed efficiently and this makes it possible to consequently reduce the chip area.

However, according to the arrangement mentioned above, swarf of wiring metal is produced when the wiring metal of the test pad 90 is cut at the dicing. The swarf causes electrical short between the internal circuit of the chip 140 and a substrate voltage (GND). This causes a problem that a process yield deteriorates. Such a problem is inevitable in the arrangement mentioned above (an arrangement in which a test pad is provided in a scribing region S) (see, for example, Publicly Known Document 2 (Japanese Unexamined Patent Publication No. 342725/2004 (Tokukai 2004-342725 published on Dec. 2, 2004)) and the like).

Moreover, according to the arrangement mentioned above, although a chip area does not increase, a scribing region S increases. This also causes a problem that an area in which the chips 140 are formed on the semiconductor wafer 150 decreases.

### SUMMARY OF THE INVENTION

The present invention is attained in view of the problems mentioned above. An object of the present invention is to realize (a) a semiconductor wafer in which (i) electrical short caused by swarf of wiring metal of each test pad does not occur in an internal circuit of each chip in a case where the test pad is provided in a scribing region, and moreover, (ii) the number of required test pads can be reduced, (b) a semiconductor chip cut from the semiconductor wafer, (c) a semiconductor device including the semiconductor chip, and (d) a wafer testing method of the semiconductor wafer.

In order to achieve the above object, a semiconductor wafer of the present invention is a semiconductor wafer on which (i) a plurality of semiconductor chips are formed so as to be arranged and aligned lengthways and crosswise and (ii) test pads for use in wafer test are provided in a scribing region that is a reserved region for dicing, the semiconductor wafer including: switch circuits each connecting a corresponding internal circuit formed in the semiconductor chip and the test pad; and switch control pads, provided in the scribing region or the semiconductor chips, whose voltages are pulled up or down to a voltage that is equal to a substrate voltage of the semiconductor wafer, the switch control pads receiving signals whose voltages are different from the substrate voltage so that the switch circuits are turned on, wherein: each of the test pads, which intervenes between the semiconductor chips adjacent to each other, is connected to at least one of the switch circuits of each of the adjacent semiconductor chips.

In the semiconductor wafer of the present invention, the test pads for the wafer test are provided in the scribing region. This makes it possible to reduce a chip area of each of the semiconductor chips. Consequently, production cost can be reduced.

Moreover, according to the configuration mentioned above, the semiconductor wafer mentioned above is provided with the switch circuits and the switch control pads. The switch control pads are provided in the scribing region or the semiconductor chips. In a case where the switch control pads are provided in the scribing region, it is possible to reduce the chip area of each of the semiconductor chips and to reduce the production cost, as with the test pads mentioned above.

Furthermore, the voltages of the switch control pads are pulled up or pulled down to a voltage that is equal to the substrate voltage of the semiconductor wafer. When a voltage that is different from the substrate voltage is provided to each of the switch control pads, each of the switch circuits is turned on. This makes it possible to keep the voltages of the switch control pads unchanged even in a case where electrical short occurs between (i) each of the test pads and each of the switch control pads and (ii) the substrate voltage during dicing. Therefore, the switch circuits are not turned on. As a result, even in a configuration in which the test pads are provided in the scribing region, electrical short between (i) each of the internal circuits in the semiconductor chip and (ii) the substrate voltage does not occur at all.

In a case where the switch control pads are provided in the semiconductor chip, it is not necessary to cut out the switch control pads during dicing. Accordingly, there is no chance of electrical short between each of the switch control pads and the substrate voltage. Therefore, even in the configuration in which the test pads are provided in the scribing region, electrical short between (i) each of the internal circuits in the semiconductor chip and (ii) the substrate voltage does not occur at all.

Moreover, each of the test pads is connected to at least one of the switch circuits of each of the adjacent semiconductor chips. Namely, the test pad is shared between the adjacent semiconductor chips. This makes it possible to reduce the number of required test pads. In other words, it becomes possible to increase the number of internal circuits which a single test pad can measure. This allows an efficient use of the test pads.

As a result, in a case where the test pads are provided in the scribing region, it becomes possible to realize the semiconductor wafer in which (i) electrical short caused by swarf of wiring metal of the test pad does not occur in the internal circuit of the semiconductor chip and (ii) the number of required test pads is reduced.

A wafer testing method of a semiconductor wafer according to the present invention is a wafer testing method of the semiconductor wafer wherein a probe needle is brought into contact with at least one of the switch control pads so that at least one of the switch circuits of a semiconductor chip to be tested only is turned on among the semiconductor chips; and a probe needle is brought into contact with the test pad so that electrical characteristics of the semiconductor chip to be tested are measured.

According to the wafer testing method, only at least one switch circuit on the semiconductor chip to be tested can be turned on among the switch circuits on the adjacent semiconductor chips. Namely, in testing the semiconductor chip to be tested, the switch circuits of the semiconductor chips other than the semiconductor chip to be tested are turned off. Therefore, the semiconductor chips other than the semiconductor chip to be tested do not influence the wafer test. According to the wafer testing method, even in the semiconductor wafer in which each of the test pads is shared by the adjacent semiconductor chips so that the number of required test pads is reduced, a predetermined wafer test can be reliably carried out. Therefore, reliability of the semiconductor chips does not decrease.

A semiconductor chip of the present invention is a semiconductor chip cut from the semiconductor wafer. Moreover, a semiconductor device of the present invention is a semiconductor device including the semiconductor chip.

The semiconductor chip cut from the semiconductor wafer, as explained above, is a semiconductor chip whose operation and the like is highly reliable. This is because electrical short between the internal circuit and a substrate voltage of the semiconductor wafer after dicing does not occur, and moreover, the wafer test for the aforesaid semiconductor chip is reliably carried out. Thus, the semiconductor chip of the present invention and the semiconductor device using the semiconductor chip of the present invention are highly reliable.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is a diagram illustrating an entire semiconductor wafer (P-type substrate) of one embodiment of the present invention.

FIG. 2 is a diagram illustrating a magnified arbitrary part of the semiconductor wafer and briefly illustrating an internal configuration of chips formed on the semiconductor wafer.

FIG. 3 is a circuit diagram illustrating one example of a configuration of a switch circuit provided in each of the chips.

FIG. 4 is a diagram illustrating a state of the chips under a wafer test.

FIG. 5 is a diagram illustrating a magnified arbitrary part of a semiconductor wafer (N-type substrate) of the one embodiment of the present invention and briefly illustrating an internal configuration of chips formed on the semiconductor wafer.

FIG. 6 is a diagram illustrating a state of the chips, formed on the semiconductor wafer as illustrated in FIG. 5, under a wafer test.

FIG. 7 is a diagram illustrating a magnified arbitrary part of a semiconductor wafer (P-type substrate) of another embodiment of the present invention and briefly illustrating an internal configuration of chips formed on the semiconductor wafer.

FIG. 8 is a diagram illustrating another example of a configuration of the semiconductor wafer as illustrated in FIG. 7.

FIG. 9 is a diagram illustrating a magnified arbitrary part of a conventional semiconductor wafer and briefly illustrating an internal configuration of chips formed on the semiconductor wafer.

FIG. 10 is a diagram illustrating a magnified arbitrary part of a semiconductor wafer (P-type substrate) of yet another embodiment of the present invention and briefly illustrating an internal configuration of chips formed on the semiconductor wafer.

FIG. 11 is a diagram illustrating an example of a configuration of a selector circuit provided in each of the chips formed on the semiconductor wafer as illustrated in FIG. 10.

FIG. 12 is a diagram illustrating a magnified arbitrary part of a semiconductor wafer (P-type substrate) of still another embodiment of the present invention and briefly illustrating an internal configuration of chips formed on the semiconductor wafer.

FIG. 13 is a diagram illustrating a magnified arbitrary part of a conventional semiconductor wafer and briefly illustrating an internal configuration of chips formed on the semiconductor wafer.

FIG. 14 is a diagram illustrating a magnified arbitrary part of a conventional semiconductor wafer and briefly illustrating an internal configuration of chips formed on the semiconductor wafer.

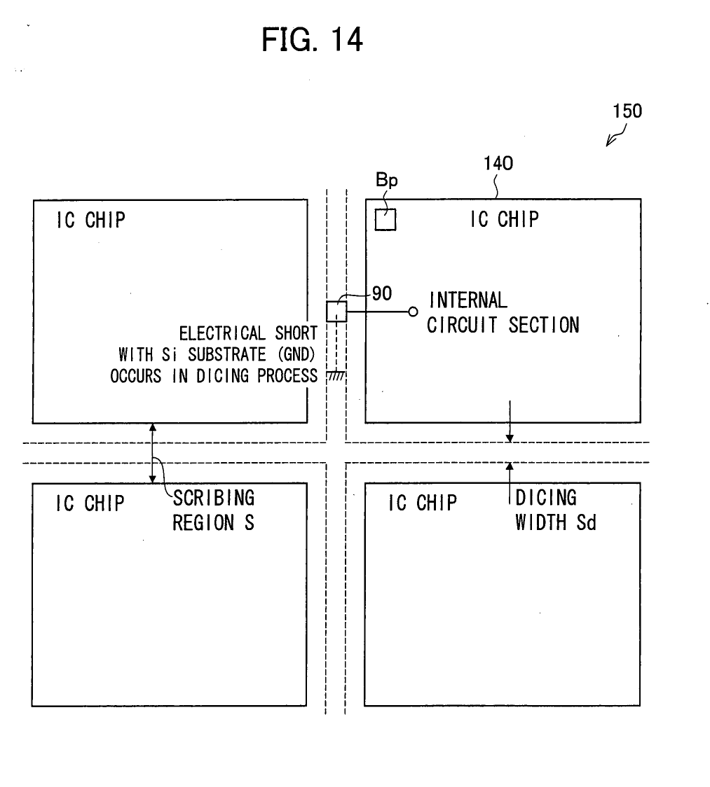

### DESCRIPTION OF THE EMBODIMENTS

### First Embodiment

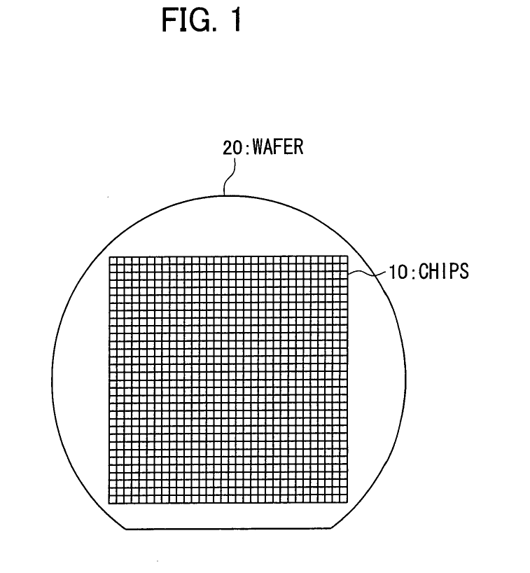

An embodiment of the present invention is explained below with reference to FIGS. 1 through 6 and Table 1.

FIG. 1 illustrates an entire semiconductor wafer 20 of the present embodiment. As illustrated in FIG. 1, chips (semiconductor chips) 10 are formed so as to be arranged and aligned lengthways and crosswise at predetermined pitches. Here, the semiconductor wafer 20 is assumed to be a P-type substrate. Therefore, a substrate voltage of the semiconductor wafer 20 is at a GND level. Here, the GND level which is the substrate voltage of the semiconductor wafer 20 is referred to as an L level, and a Vcc level (a voltage different from the substrate voltage) is referred to as an H level.

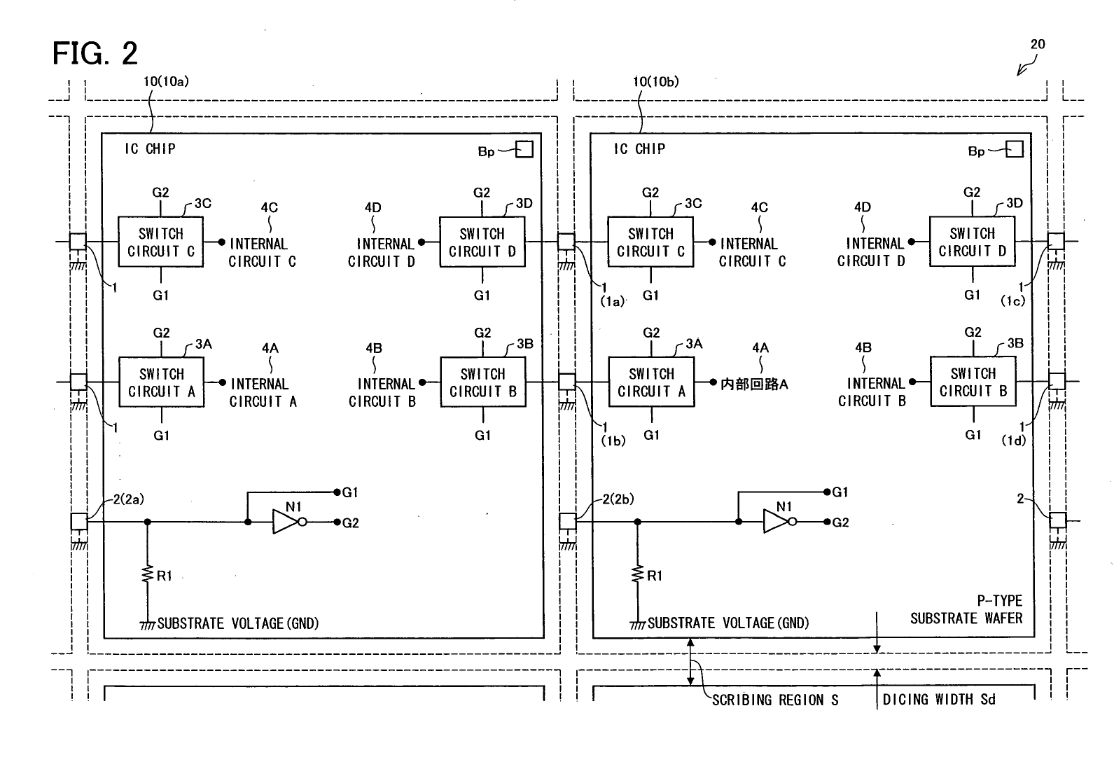

FIG. 2 illustrates a magnified arbitrary part of the semiconductor wafer 20. Moreover, FIG. 2 briefly illustrates each internal configuration of the chips 10. Both of chips 10a and 10b indicate the chip 10. A scribing region S in FIG. 2 is a reserved region for dicing (a region where dicing is carried out) as mentioned in the background of the invention. A dicing width Sd is a part to be removed by dicing. Moreover, bonding pads Bp (note that only one bonding pad is illustrated in FIG. 2) are pads to be used in an assembly process mentioned in the background of the invention.

Test pads 1 for wafer test and switch control pads 2 are provided in the scribing region S (dicing width Sd) of the semiconductor wafer 20. Each of the switch control pads 2 is set to an H level by a probe needle of a probe card during the wafer testing so that switch circuits 3A through 3D (later described) operate.

As mentioned above, the test pads 1 and the switch control pads 2 are provided in the scribing region S on the semiconductor wafer 20. This makes it possible to remove the test pads 1, which are necessary only for a wafer test, during dicing so that only necessary pads (bonding pads Bp) are left. Thus, it is possible to (i) efficiently form pads and (ii) reduce each chip area. This allows a reduction in production cost.

Each of the chips 10 includes the switch circuits 3A through 3D and internal circuits 4A through 4D. The switch circuits connect the internal circuits and the test pads, respectively. For example, the switch circuit 3A as illustrated in FIG. 2 connects the internal circuit 4A and the test pad 1 (1b). Similar connections are carried out with respect to other switch circuits, respectively.

As illustrated in FIG. 2, each of the test pads 1 is connected to both of (i) one of the switch circuits of the chip 10a and (ii) one of the switch circuits of the chip 10b. For example, the test pad 1a is connected to both of the switch circuit 3D of the chip 10a and the switch circuit 3C of the chip 10b. Namely, the test pad 1 is shared by the chips 10a and 10b. This makes it possible to reduce the number of required test pads. Consequently, the scribing region S can be reduced and it is possible to increase an effective area, where the chips 10 are formed, on the semiconductor wafer 20. In other words, it becomes possible to increase the number of internal circuits which a single test pad can measure. This allows an efficient use of the test pads.

Each of the switch control pads 2 is connected to a pulldown resistor R1. A voltage of the switch control pad 2 is pulled down to the L level. Moreover, the switch control pad 2 is connected to an inverter N1. A node of the switch control pad 2 and an input terminal of the inverter N1 is connected to each of terminals G1 of the switch circuits 3A through 3D in FIG. 2. An output terminal of the inverter N1 is connected to each of terminals G2 of the switch circuits 3A through 3D in FIG. 2.

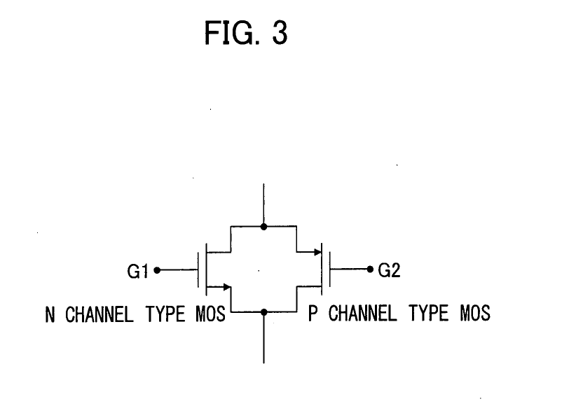

FIG. 3 illustrates a specific example of a configuration of the switch circuits 3A through 3D.

As illustrated in FIG. 3, each of the switch circuits 3A through 3D is a general transfer gate circuit that is constituted by an N channel type MOS (Metal Oxide Semiconductor) transistor (Hereinafter, referred to as an NMOS) and a P channel type MOS transistor (Hereinafter, referred to as a PMOS). A gate terminal of the NMOS is the terminal G1 mentioned above and a gate terminal of the PMOS is the terminal G2 mentioned above.

Next, an operation of each of the switch circuits 3A through 3D is explained with reference to Table 1. A control signal S1 is a signal provided to the terminal G1. Namely, the control signal S1 is a voltage at the node of the switch control pad 2 and the input terminal of the inverter N1. A control signal S2 is a signal provided to the terminal G2. Namely, the control signal S2 is a voltage at the output terminal of the inverter N1.

TABLE 1

| | | SWITCH CIRCUITS |
|---|---|---|
| S1 | S2 | 3A–3D |
| L | H | OFF |
| H | L | ON |

As shown in Table 1, when the terminal G1 receives the control signal S1 of the L level and the terminal G2 receives the control signal S2 of the H level, each of the switch circuits 3A through 3D is turned off. This causes electrical discontinuity between (i) each of the internal circuits 4A through 4D and (ii) each of the test pads 1 to which the internal circuits 4A through 4D are respectively connected. Under normal conditions (in a time other than wafer test time), the terminal G1 and the terminal G2 respectively receive the control signal S1 of the L level and the control signal S2 of the H level (because, as mentioned above, the voltage of the switch control pad 2 is pulled down to the L level by the pulldown resistor R1). Namely, each of the test pads 1 and each of the internal circuits 4A through 4D are electrically discontinuous under the normal conditions.

On the other hand, as shown in Table 1, when the terminal G1 receives the control signal S1 of the H level and the terminal G2 receives the control signal S2 of the L level, each of the switch circuits 3A through 3D is turned on. This causes electrical continuity between (i) each of the internal circuits 4A through 4D and (ii) each of the test pads 1 to which the internal circuits 4A through 4D are respectively connected. During the wafer test time, the terminal G1 and the terminal G2 respectively receive the control signal S1 of the H level and the control signal S2 of the L level (because, as mentioned above, the voltage of the switch control pad 2 becomes H level due to the probe needle of the probe card). Namely, during the wafer test time, each of the test pads 1 and each of the internal circuits 4A through 4D are electrically continuous.

Because the semiconductor wafer 20 has the configuration mentioned above, the voltage of the switch control pad 2 does not change even in a case where a short circuit occurs between (i) the test pad 1 and the switch control pad 2 and (ii) the substrate voltage at the dicing. Therefore, the switch circuits 3A through 3D are not turned on. Unless each of the switch circuits 3A through 3D is turned on, each of the test pads 1 and each of the internal circuits 4A through 4D are electrically discontinuous. This prevents an occurrence of a short circuit between each of the internal circuits 4A through 4D and the substrate voltage after dicing, even in a case where each of the test pads 1 is provided in the scribing region S.

In this embodiment, the switch control pad 2 is provided in the scribing region S. However, the position of the switch control pad 2 is not limited to this. The switch control pad 2 may be provided in the chip 10. In such a case, because it becomes unnecessary to cut out the switch control pad 2 during dicing, there is no chance of an electrical short between the switch control pad 2 and the substrate voltage. As a result, a short circuit between each of the internal circuits 4A through 4D and the substrate voltage does not occur at all.

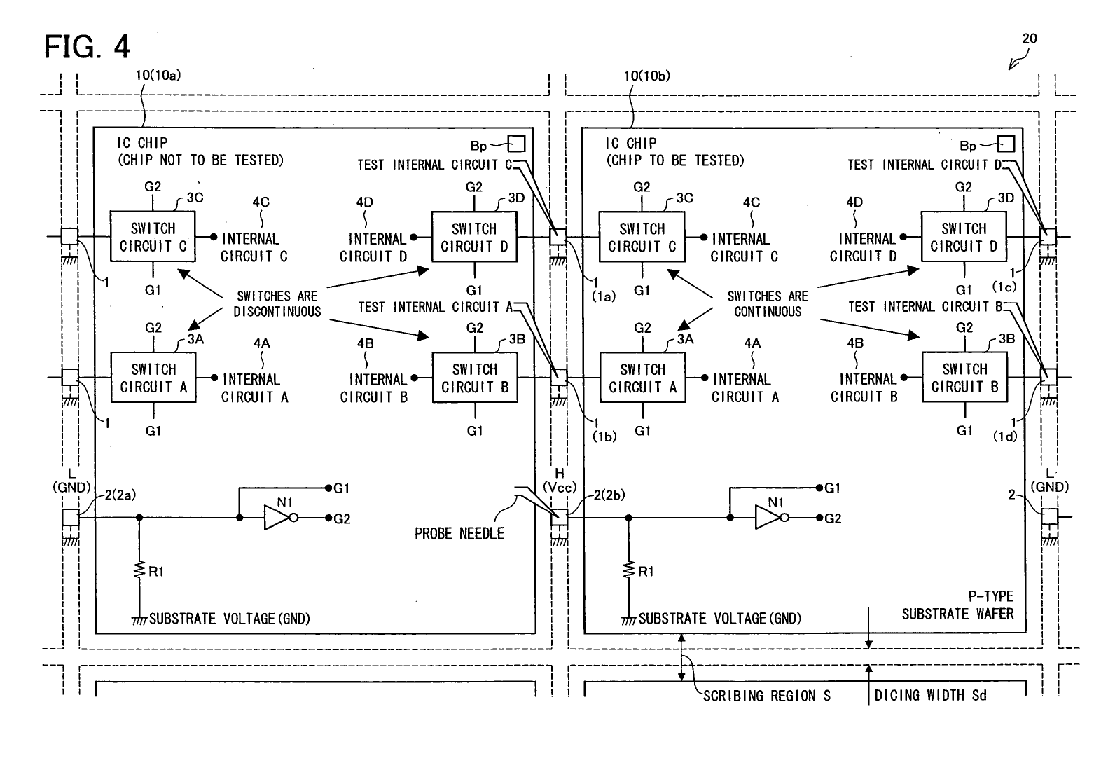

Next, with reference to FIG. 4, a wafer testing method is explained. An example explained is a case where the chip 10b is subjected to a wafer test.

FIG. 4 is a diagram illustrating a state of the chip 10b under the wafer test.

At the beginning of the wafer test, the switch control pad 2 of the chip (chip 10b) to be tested is set to the H level by the probe needle of the probe card (Here, the switch control pad 2b in FIG. 4 is set to the H level.) According to this, the control signal S1 and the control signal S2 respectively become the H level and the L level. Therefore, all of the switch circuits 3A through 3D of the chip 10b are turned on.

When all of the switch circuits 3A through 3D of the chip 10b are turned on, each of the internal circuits 4A through 4D and each of the test pads 1 to which the internal circuits 4A through 4D are respectively connected become electrically continuous. Then, the internal circuits 4A through 4D are tested via the respective test pads 1, as illustrated in FIG. 4.

At this time, the switch control pad 2 (switch control pad 2a) of the chip 10a adjacent to the chip 10b stays at the L level (the switch control pad 2a stays at the L level unless the switch control pad 2a is set to the H level.). Therefore, all of the switch circuits 3A through 3D of the chip 10a are turned off. This causes an electrical discontinuity between each of the internal circuits 4A through 4D of the chip 10a and each of the test pads 1 respectively connected to the internal circuits 4A through 4D.

Namely, even if each of the test pads is shared by adjacent chips, measurement for the chip to be tested is not influenced by its adjacent chip at the testing of the chip to be tested. As a result, even when the number of required test pads is reduced, it is possible to carry out a predetermined wafer test, so that reliability of the chips does not decrease.

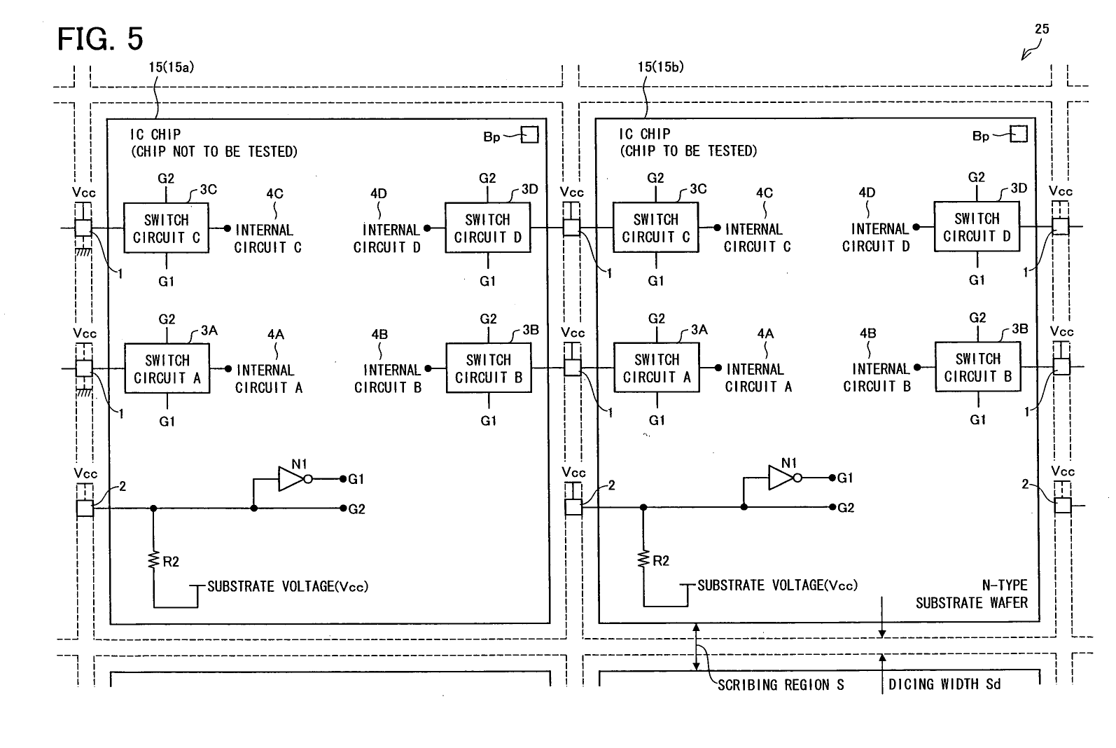

In the case explained in this embodiment, the semiconductor wafer 20 is a P-type substrate. However, the embodiment is not limited to this. The semiconductor wafer 20 may be an N-type substrate (semiconductor wafer 25). Even in such a case, the same effect as explained above can be attained. FIG. 5 briefly illustrates an internal configuration of chips 15 formed on the semiconductor wafer 25. Members given the same reference numerals as the members illustrated in FIG. 2 respectively have identical functions and the explanations thereof are omitted. Moreover, both of chips 15a and 15b indicate the chip 15.

In this case, the substrate voltage of the semiconductor wafer 25 is at the H level. Accordingly, as illustrated in FIG. 5, the switch control pad 2 is pulled up to the H level via a pullup resistor R2. Moreover, a position where the inverter N1 is connected is changed so that the control signal S1 of the L level and the control signal S2 of the H level are normally given respectively to the terminals G1 and the terminals G2 of the switch circuits 3A through 3D. The configuration other than this is the same as the chips 10.

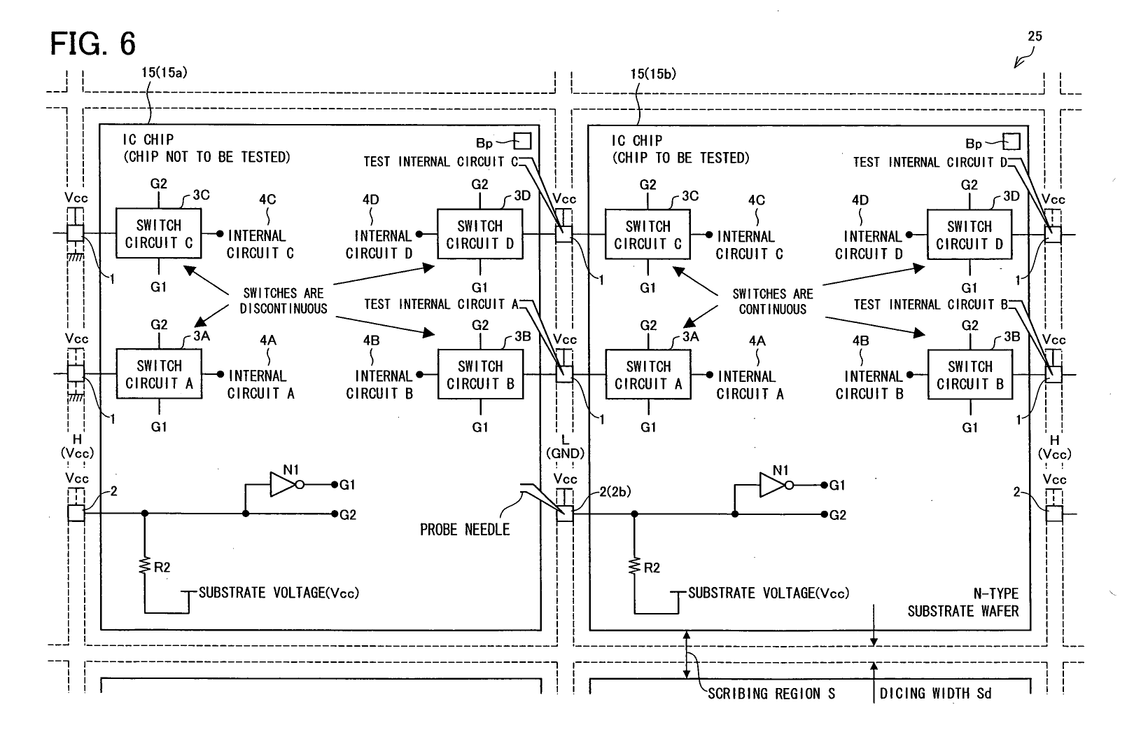

FIG. 6 is a diagram illustrating a state of the semiconductor wafer 25 under the wafer test. A chip to be tested is the chip 15b. In this case, at the beginning of the wafer test, the switch control pad 2 of the chip to be tested (chip 15b) is set to the L level by the probe needle of the probe card (Here, the switch control pad 2b illustrated in FIG. 6 is set to the L level). This makes it possible to test the internal circuits 4A through 4d in the same manner as the wafer test of the semiconductor wafer 20.

### Second Embodiment

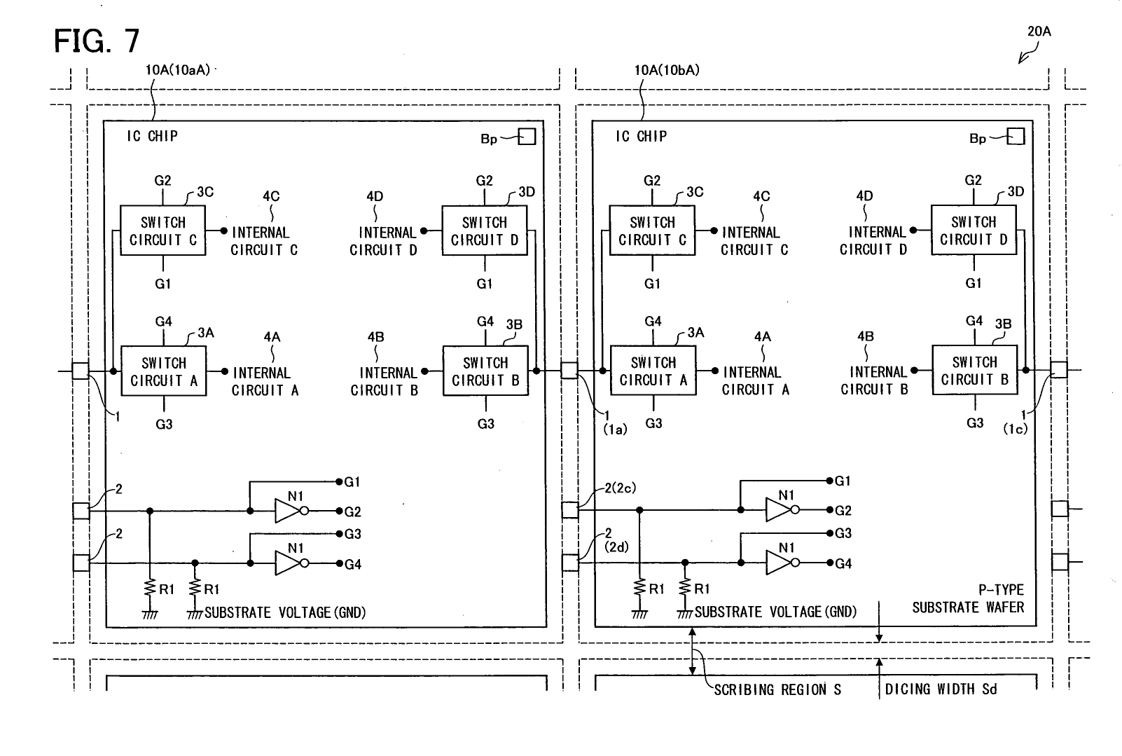

With reference to FIG. 7, another embodiment of the present invention is explained as follows.

FIG. 7 is a diagram illustrating a magnified arbitrary part of a semiconductor wafer 20A according to the present embodiment. Moreover, FIG. 7 also briefly illustrates an internal configuration of chips 10A formed on the semiconductor wafer 20A. The semiconductor wafer 20A is a P-type substrate. Both of chips 10aA and 10bA indicate the chip 10A. Furthermore, members given the same reference numerals as the members explained in the first embodiment respectively have identical functions and the explanations thereof are omitted.

The semiconductor wafer 20A has a configuration in which the number of required test pads can be further reduced, in addition to the effect attained by the semiconductor wafer 20. Specifically, in the configuration, plural switch circuits of each of adjacent chips are connected to one test pad. An example explained here is a case where two switch circuits of each of the adjacent chips are connected to one test pad.

As illustrated in FIG. 7, (i) test pads 1 and (ii) two switch control pads 2 (switch control pads 2c and 2d) for each chip 10A are provided in a scribing region S (dicing width Sd) of the semiconductor wafer 20A.

The test pad 1 is connected to two switch circuits of the chip 10aA and two switch circuits of the chips 10bA. Specifically, the test pad 1a is connected to switch circuits 3B and 3D of the chip 10aA and switch circuits 3A and 3C of the chip 10bA.

By connecting plural switch circuits of each of the adjacent chips to one test pad in this way, the number of required test pads can be reduced, compared with the number of test pads in a configuration in which one test pad is connected to one switch circuit of each of the adjacent chips as in the first embodiment. In other words, it becomes possible to increase the number of internal circuits which a single test pad can measure. This allows more efficient use of the test pads.

Each of switch control pads 2c and 2d is connected to a pulldown resistor R1. Respective voltages of the switch control pads 2c and 2d are pulled down to an L level.

Moreover, each of the switch control pads 2c and 2d is connected to an inverter N1. A node of the switch control pad 2c and an input terminal of the inverter N1 is connected to the terminals G1 of the switch circuits 3C and 3D, and the output terminal of the inverter N1 is connected to the terminals G2 of the switch circuits 3C and 3D.

Moreover, the node of the switch control pad 2d and the input terminal of the inverter N1 is connected to the terminals G1 (referred to as G3 here) of switch circuits 3A and 3B and the output terminal of the inverter N1 is connected to the terminals G2 (referred to as G4 here) of the switch circuits 3A and 3B.

Next, a wafer testing method of the semiconductor wafer 20A is explained. Assume that a chip to be tested is the chip 10bA.

At the beginning of the wafer test, the switch control pad 2 connected to the chip to be tested is set to an H level by a probe needle of a probe card, in the same manner as the wafer test of the first embodiment. However, in the present embodiment, unlike the first embodiment, the internal circuits 4A through 4D are tested one after another because plural switch circuits of each of the adjacent chips are connected to the one test pad. Specifically, the internal circuits 4C and 4D are tested at one time, and then the internal circuits 4A and 4B are tested at one time. Detailed explanation is given below.

First, in order to test the internal circuits 4C and 4D, the switch control pad 2c is set to the H level. By setting the switch control pad 2c to the H level, only the switch circuits 3C and 3D are turned on. As a result, the test pad 1a and the internal circuit 4C become electrically continuous, and the test pad 1c and the internal circuit 4D become electrically continuous. Consequently, the testing of the internal circuits 4C and 4D becomes possible.

Moreover, in order to test the internal circuits 4A and 4B, the switch control pad 2d is set to the H level. By setting the switch control pad 2d to the H level, only the switch circuits 3A and 3B are turned on. As a result, the test pad 1a and the internal circuit 4A become electrically continuous, and the test pad 1c and the internal circuit 4B become electrically continuous. Consequently, the testing of the internal circuits 4A and 4B becomes possible.

As in the first embodiment, at this time, the switch control pads 2 (There are two switch control pads 2 for the chip 10aA like the switch control pads 2c and 2d) of the chip 10aA adjacent to the chip 10bA stay at the L level (The switch control pads 2 of the chip 10aA stay at the L level unless they are set to the H level by the probe needle). Therefore, all of the switch circuits 3A through 3D of the chip 10aA are turned off.

Namely, even if each of the test pads is shared by adjacent chips, measurement for the chip to be tested is not influenced by its adjacent chip at the testing of the chip to be tested. As a result, even when the number of required test pads is reduced, it is possible to carry out a predetermined wafer test, so that reliability of the chips does not decrease.

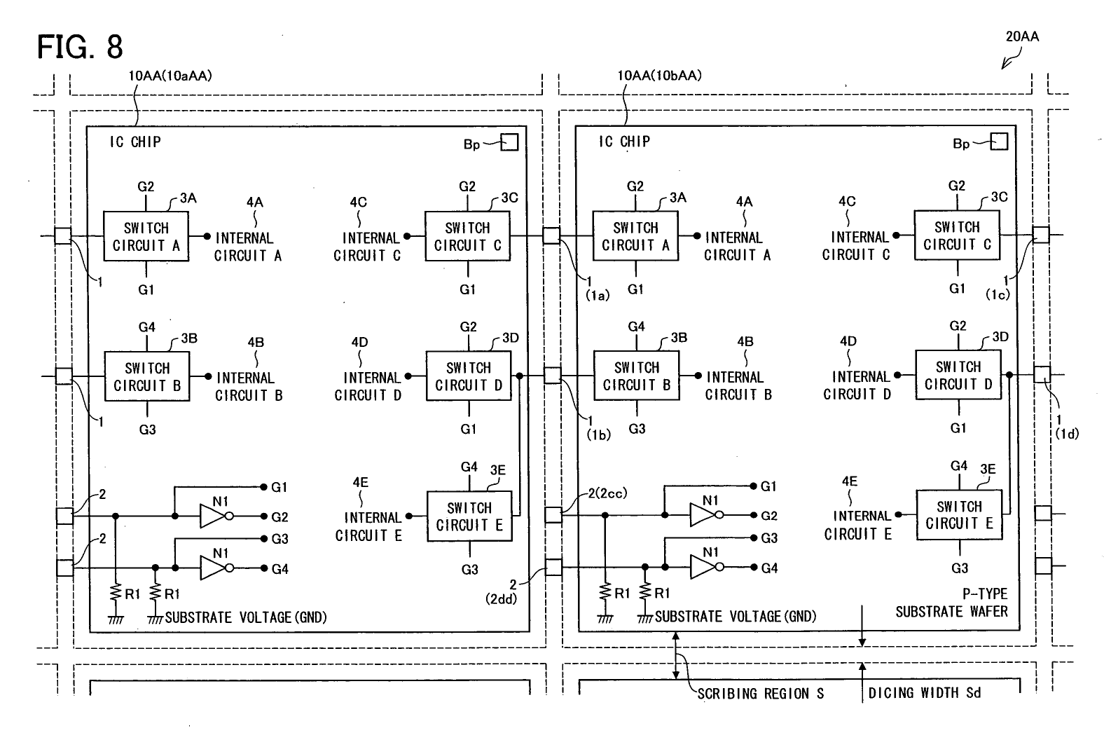

Next, anther example of a configuration of the semiconductor wafer 20A (referred to as a semiconductor wafer 20AA) is explained as follows with reference to FIG. 8.

FIG. 8 is a diagram illustrating a magnified arbitrary part of a semiconductor wafer 20AA. Moreover, FIG. 8 also briefly illustrates an internal configuration of chips 10AA formed on the semiconductor wafer 20AA. The semiconductor wafer 20AA is a P-type substrate. Both of chips 10aAA and 10bAA indicate the chip 10AA. Furthermore, members given the same reference numerals as the members explained above respectively have identical functions and the explanations thereof are omitted.

As illustrated in FIG. 8, (a) the test pads 1 and (b) two switch control pads 2 for each chip 10AA are provided in a scribing region S (dicing width Sd) of the semiconductor wafer 20AA.

The chip 10AA is provided with switch circuits 3A through 3E and internal circuits 4A through 4E. As illustrated in FIG. 8, the internal circuits are different in number on respective edges of the adjacent chips where the edges of the adjacent chips face each other. Specifically, the internal circuits 4C through 4E are provided on the edge of the chip 10aAA facing the chip 10bAA. The internal circuits 4A and 4B are provided on the edge of the chip 10bAA facing the chip 10aAA.

Each of the test pads 1 is connected to the switch circuits as illustrated in FIG. 8. Specifically, the test pad 1a is connected to the switch circuit 3C of the chip 10aAA and the switch circuit 3A of the chip 10bAA. Moreover, the test pad 1b is connected to the switch circuits 3D and 3E of the chip 10aAA and the switch circuit 3B of the chip 10bAA.

Each of the switch control pads 2cc and 2dd is connected to the pulldown resistor R1. The respective voltages of the switch control pads 2cc and 2dd are pulled down to the L level.

Moreover, each of the switch control pads 2cc and 2dd is connected to the inverter N1. A node of the switch control pad 2cc and an input terminal of the inverter N1 is connected to the terminals G1 of the switch circuits 3A, 3C, and 3D, and the output terminal of the inverter N1 is connected to the terminals G2 of the switch circuits 3A, 3C, and 3D.

Moreover, a node of the switch control pad 2dd and the input terminal of the inverter N1 is connected to the terminals G1 (referred to as G3 here) of switch circuits 3B and 3E, and the output terminal of the inverter N1 is connected to the terminals G2 (referred to as G4 here) of the switch circuits 3B and 3E.

Next, a wafer testing method of the semiconductor wafer 20AA is explained. A chip to be tested is the chip 10bAA.

At the beginning of the wafer test, the switch control pad 2 connected to the chip to be tested is set to the H level by the probe needle of the probe card, as in the wafer testing method of the first embodiment. However, in the present embodiment, unlike the first embodiment, the internal circuits 4A through 4E are tested one after another because plural switch circuits of the adjacent chips are connected to one test pad. Specifically, the internal circuits 4A, 4C, and 4D are tested at one time, and then, the internal circuits 4B and 4E are tested at one time. Detailed explanation is given below.

First, in order to test the internal circuits 4A, 4C, and 4D, the switch control pad 2cc is set to the H level. By setting the switch control pad 2cc to the H level, only the switch circuits 3A, 3C, and 3D are turned on. As a result, the test pad 1a and the internal circuit 4A become electrically continuous, the test pad 1c and the internal circuit 4C become electrically continuous, and the test pad 1d and the internal circuit 4D become electrically continuous. Consequently, the testing of the internal circuits 4A, 4C, and 4D becomes possible.

Next, in order to test the internal circuits 4B and 4E, the switch control pad 2dd is set to the H level. By setting the switch control pad 2dd to the H level, only the switch circuits 3B and 3E are turned on. As a result, the test pad 1b and the internal circuit 4B become electrically continuous, and the test pad 1d and the internal circuit 4E become electrically continuous. Consequently, the testing of the internal circuits 4B and 4E becomes possible.

Even in a case where the internal circuits are different in number on respective edges of the adjacent chips where the edges of the adjacent chips face each other, the configuration mentioned above allows the test pads to be shared in the semiconductor wafer 20AA by controlling on/off of the switch circuits connected to the internal circuits.

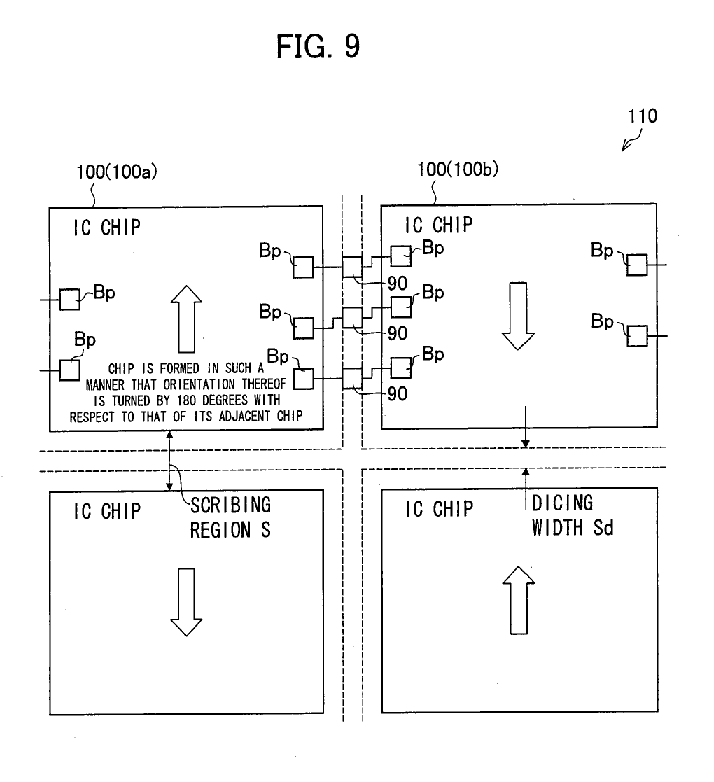

With reference to FIG. 9, as a comparative example, a conventional configuration (Publicly Known Document 2) is explained below. In the conventional configuration explained below, a test pad is shared in a case where the internal circuits are different in number on the respective edges of the adjacent chips where the edges of the adjacent chips face each other.

FIG. 9 is a diagram illustrating a magnified arbitrary part of a conventional semiconductor wafer 110 as described in Publicly Known Document 2. Moreover, FIG. 9 briefly illustrates an internal configuration of chips 100 formed on the semiconductor wafer 110. The arrows in FIG. 9 respectively indicate directions of the chips 100. Both of chips 100a and 100b indicate the chip 100.

As illustrated in FIG. 9, on the semiconductor wafer 110, the adjacent chips 100 are formed in such a manner that their circuit patterns are turned by 180 degrees with respect to each other. With this arrangement, bonding pads Bp are identical in number on the respective edges of the adjacent chips 100 where the edges of the adjacent chips 100 face each other. Specifically, as illustrated in FIG. 9, the circuit pattern of the chip 100a is turned by 180 degrees with respect to the circuit pattern of the chip 10b. Accordingly, each of the chips 100a and 100b has three bonding pads Bp, in other words, the same number of the bonding pads Bp on the respective edges of the chips 100a and 100b where the edges of the chips 100a and 100b face each other. As a result, on the semiconductor wafer 110, adjacent chips 100 share test pads 90.

However, in picking up the chips 100 in an assembly process, such an arrangement requires a process for changing the orientations of the chips 100 so that the chips 100 are in the same orientation (For example, it is necessary to pick up the alternate chips 100 and then, rotate the semiconductor wafer 110 so as to pick up the rest of the chips 100). This leads to a cost increase.

However, in the semiconductor wafer 20AA mentioned above, it is not necessary to rotate the circuit pattern in the adjacent chips. Accordingly, the above mentioned unproductive process in the assembly process is not necessary; therefore, the cost increase does not occur.

Although the semiconductor wafer 20A (the semiconductor wafer 20AA) explained here is the P-type substrate, the substrate may be an N-type as in the first embodiment. Moreover, regarding the semiconductor wafer 20A, in the case explained as an example, a single test pad is connected to two switch circuits of each of the adjacent chips. However, the configuration is not limited to this. Namely, two or more switch circuits of each of the adjacent chips may be connected to the single test pad. In such a case, it is necessary to increase the number of switch control pads in accordance with the number of switch circuits connected to the single test pad.

### Third Embodiment

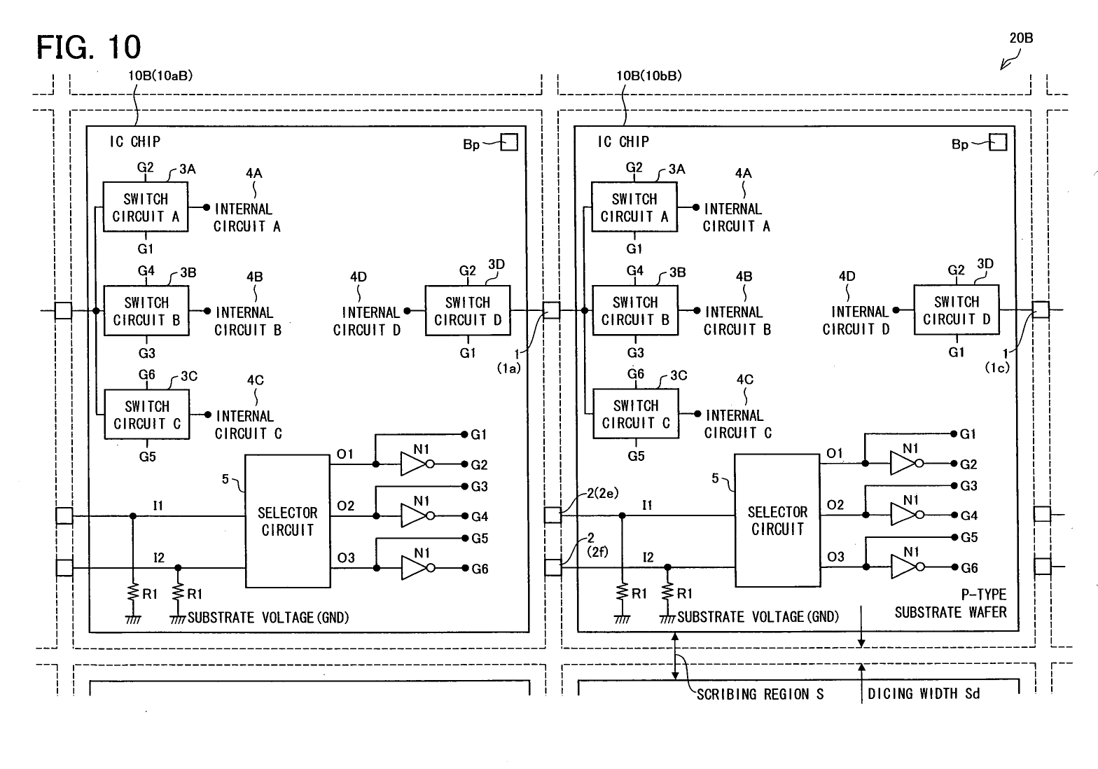

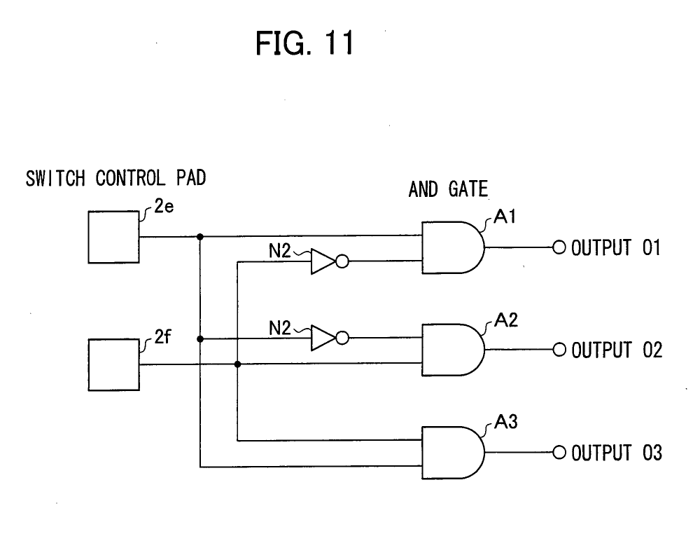

With reference to FIGS. 10 and 11, and Table 2, yet another embodiment of the present invention is explained as follows.

FIG. 10 is a diagram illustrating a magnified arbitrary part of a semiconductor wafer 20B. FIG. 10 also briefly illustrates an internal configuration of chips 10B formed on the semiconductor wafer 20B. Here, the semiconductor wafer 20B is a P-type substrate. Both chips 10aB and 10bB indicate the chip 10B. Moreover, members given the same reference numerals as the members explained in the first embodiment respectively have identical functions and the explanations thereof are omitted.

In addition to the effect attained by the semiconductor wafer 20, the semiconductor wafer 20B has a configuration in which the number of required test pads can be reduced further as with a semiconductor wafer 20A. Specifically, each of the test pads is connected to three switch circuits in one of the chips 10B. Moreover, as with the semiconductor wafer 20AA, on the semiconductor wafer 20B, the test pads can be shared even in a case where the internal circuits are different in number on the respective edges of the adjacent chips where the edges of the adjacent chips face each other.

As illustrated in FIG. 10, (a) test pads 1 and (b) two switch control pads 2 for each chip 10B are provided in a scribing region S (dicing width Sd) of the semiconductor wafer 20B.

The test pads 1 are connected to the switch circuits as illustrated in FIG. 10. Specifically, the test pad 1a is connected to the switch circuit 3D of the chip 10aB and the switch circuits 3A through 3C of the chip 10bB.

By connecting plural switch circuits to one test pad in this way, the number of required test pads can be reduced, compared with the number of required test pads in a configuration in which one test pad is connected to one switch circuit of each of the adjacent chips as in the first embodiment. In other words, it becomes possible to increase the number of internal circuits which a single test pad can measure. This allows more efficient use of the test pads.

Each of the switch control pads 2e and 2f is connected to a pulldown resistor R1. Respective voltages of the switch control pads 2e and 2f are pulled down to the L level. Moreover, the switch control pads 2e and 2f are connected to a selector circuit 5, which controls on/off of the switch circuits 3A through 3D.

FIG. 11 illustrates an example of a configuration of the selector circuit 5.

The selector circuit 5, as illustrated in FIG. 11, is constituted by three AND circuits A1 through A3 and two inverters N2. One input terminal of the AND circuit A1 is connected to the switch control pad 2e (input terminal I1), and the other input terminal of the AND circuit A1 is connected to the switch control pad 2f (input terminal I2) via the inverter N2. One input terminal of the AND circuit A2 is connected to the switch control pad 2e via the inverter N2, and the other input terminal of the AND circuit A2 is connected to the switch control pad 2f. One input terminal of the AND circuit A3 is connected to the switch control pad 2e, and the other input terminal of the AND circuit A3 is connected to the switch control pad 2f.

Output terminals of the AND circuits A1 through A3 respectively correspond to output terminals O1 through O3 of the selector circuit 5.

The output terminals O1 through O3 of the selector circuit 5 are connected respectively to inverters N1. A node of the output terminal O1 of the selector circuit 5 and the input terminal of the inverter N1 is connected to the terminals G1 of the switch circuits 3A and 3D. Moreover, the output terminal of the inverter N1 is connected to the terminals G2 of the switch circuits 3A and 3D.

A node of the output terminal O2 of the selector circuit 5 and the input terminal of the inverter N1 is connected to the terminal G1 (referred to as G3 here) of the switch circuit 3B. Moreover, the output terminal of the inverter N1 is connected to the terminal G2 (referred to as G4 here) of the switch circuit 3B. Furthermore, a node of the output terminal O3 of the selector circuit 5 and the input terminal of the inverter N1 is connected to the terminal G1 (referred to as G5 here) of the switch circuit 3C. Moreover, the output terminal of the inverter N1 is connected to the terminal G2 (referred to as G6 here) of the switch circuit 3C.

Next, with reference to Table 2, operation of the selector circuit 5 is explained as follows. “L” and “H” in Table 2 respectively indicate an L level voltage of the terminal and an H level voltage of the terminal. For example, “L” at the input terminal I1 means that a voltage of the input terminal I1 is at an L level. The voltage of the input terminal I1 is a voltage of the switch control pad 2e and a voltage of the input terminal I2 is a voltage of the switch control pad 2f.

TABLE 2

| | |
|---|---|
| INPUT | OUTPUT |

| I1 | I2 | O1 | O2 | O3 |
|---|---|---|---|---|
| L | L | L | L | L |
| H | L | H | L | L |
| L | H | L | H | L |
| H | H | L | L | H |

First, in a case where both of the voltages of the input terminals I1 and I2 are at the L level, in other words, under the normal conditions, all of the voltages of the output terminals O1 through O3 are at the L level. Therefore, all of the switch circuits 3A through 3D are turned off. Next, in a case where the voltage of the input terminal I1 is at the H level and the voltage of the input terminal I2 is at the L level, the voltage of only the output terminal O1 becomes the H level. Accordingly, only the switch circuits 3A and 3D are turned on.

Next, in a case where the voltage of the input terminal I1 is at the L level and the voltage of the input terminal I2 is at the H level, the voltage of only the output terminal O2 becomes the H level. Accordingly, only the switch circuit 3B is turned on. Moreover, in a case where the voltages of both of the input terminals I1 and I2 are at the H level, only the voltage of the output terminal O3 becomes the H level. Accordingly, only the switch circuit 3C is turned on. In this way, the selector circuit 5 makes it possible to turn on only a target switch circuit or target switch circuits.

Next, a wafer testing method of the semiconductor wafer 20B is explained. A chip to be tested is the chip 10bB.

At the beginning of the wafer testing, the switch control pad 2 connected to the chip to be tested is set to the H level by a probe needle of a probe card, as with the wafer testing method described in the first embodiment. In the present embodiment, the internal circuits 4A and 4D are tested at one time. Detailed explanation is given below.

First, in order to test the internal circuits 4A and 4D, the voltage of the input terminal I1 and the voltage of the input terminal I2 are set respectively to the H level and the L level as is clear from the explanation above concerning the operation of the selector circuit 5. Namely, the switch control pad 2e is set to the H level. By setting the switch control pad 2e to the H level, only the switch circuits 3A and 3D are turned on. As a result, the test pad 1a and the internal circuit 4A become electrically continuous, and the test pad 1c and the internal circuit 4D become electrically continuous. Therefore, the testing of the internal circuits 4A and 4D becomes possible.

Next, in order to test the internal circuit 4B, the voltage of the input terminal I1 is set to the L level, and the voltage of the input terminal I2 is set to the H level. Namely, the switch control pad 2f is set to the H level. By setting the switch control pad 2f to the H level, only the switch circuit 3B is turned on. As a result, the test pad 1a and the internal circuit 4B become electrically continuous. Consequently, the testing of the internal circuit 4B becomes possible.

Furthermore, in order to test the internal circuit 4C, the voltages of both of the input terminals I1 and I2 are set to the H level. Namely, the switch control pads 2e and 2f are set to the H level. By setting the switch control pads 2e and 2f to the H level, only the switch circuit 3C is turned on. As a result, the test pad 1a and the internal circuit 4C become electrically continuous. Consequently, the testing of the internal circuit 4C becomes possible.

At this time, as in the first embodiment, the switch control pads 2 (There are two switch control pads 2 to the chip 10aB like the switch control pads 2e and 2f) of the chip 10aB adjacent to the chip 10bB stay at the L level (Each of the switch control pads 2 of the chip 10aB stays at the L level unless the switch control pads 2 are set to the H level by the probe needle). Accordingly, all the switch circuits 3A through 3D of the chip 10aB are turned off.

Namely, even if each of the test pads is shared by adjacent chips, measurement for the chip to be tested is not influenced by its adjacent chip at the testing of the chip to be tested. As a result, even when the number of required test pads is reduced, it is possible to carry out a predetermined wafer test, so that reliability of the chips does not decrease.

Although a case where the semiconductor wafer 20B is the P-type substrate is explained here, the semiconductor wafer 20B may be an N-type substrate, as in the first embodiment. Moreover, a case explained as the example has a test pad connected to three switch circuits of one of the adjacent chips. However, the number of the switch circuits connected to one test pad is not limited to this.

### Fourth Embodiment

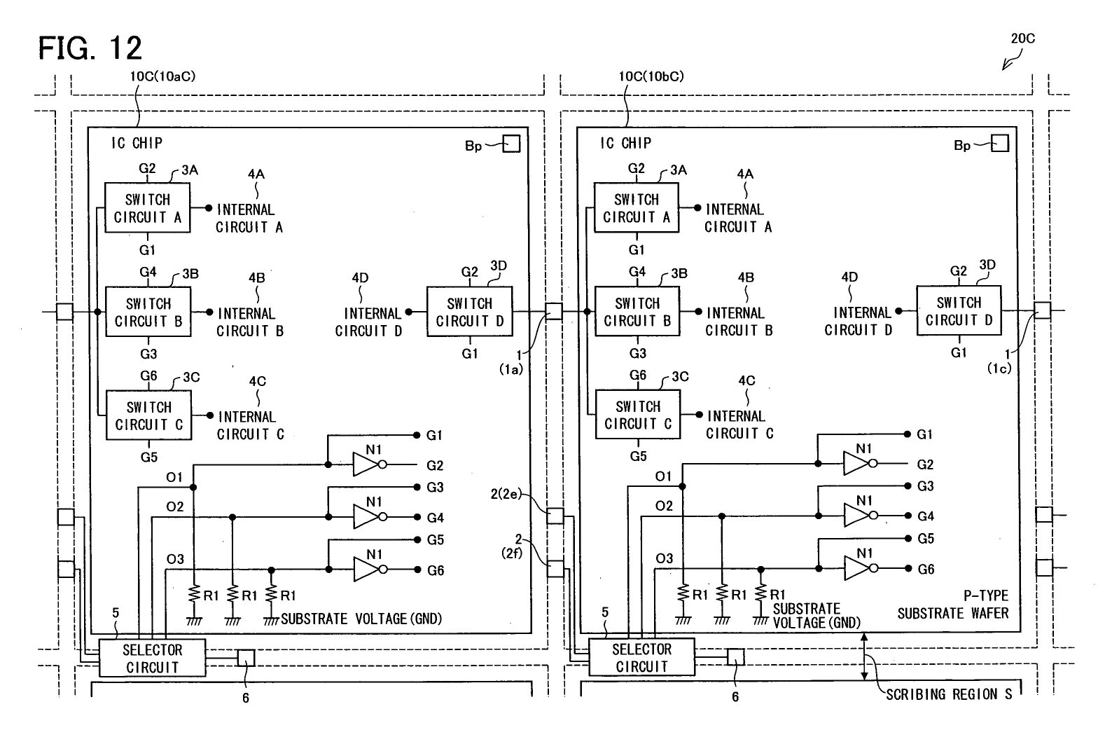

With reference to FIG. 12, still another embodiment of the present invention is explained as follows.

FIG. 12 is a diagram illustrating a magnified arbitrary part of a semiconductor wafer 20C. FIG. 12 also briefly illustrates an internal configuration of chips 10C formed on the semiconductor wafer 20C. Here, the semiconductor wafer 20C is a P-type substrate. Both chips 10aC and 10bC indicate the chip 10C. Moreover, members given the same reference numerals as the members explained in the first embodiment respectively have identical functions and the explanations thereof are omitted.

As illustrated in FIG. 12, the semiconductor wafer 20C has a configuration in which a selector circuit 5 of the semiconductor wafer 20B of the third embodiment and a source supply pad 6 for the selector circuit 5 are provided in a scribing region S. The selector circuit 5 is used only at wafer testing and not necessary after dicing. Accordingly, provision of the selector circuit 5 in the scribing region S not only brings the effect attained by the semiconductor wafer 20B but also eliminates the need for a nonessential circuit provided in a chip, which allows chip area to be reduced correspondingly. Therefore, production cost can be reduced. In other words, this allows more circuits to be built in the chips.

In the last place, as a comparative example explained is a conventional technique aiming at solving the problem that occurs after dicing and is caused by providing test pads in the scribing region. The problem is also one of problems to be solved in the present invention. For example, Publicly Known Document 3 (Japanese Unexamined Patent Publication No. 120308/1994 (Tokukaihei 6-120308) (published on Apr. 28, 1994)), in order to solve the problem mentioned above, discloses that test pads provided in the scribing region are removed during a photolithography process before dicing. However, in this case, the photolithography process mentioned above leads to a significant cost increase.

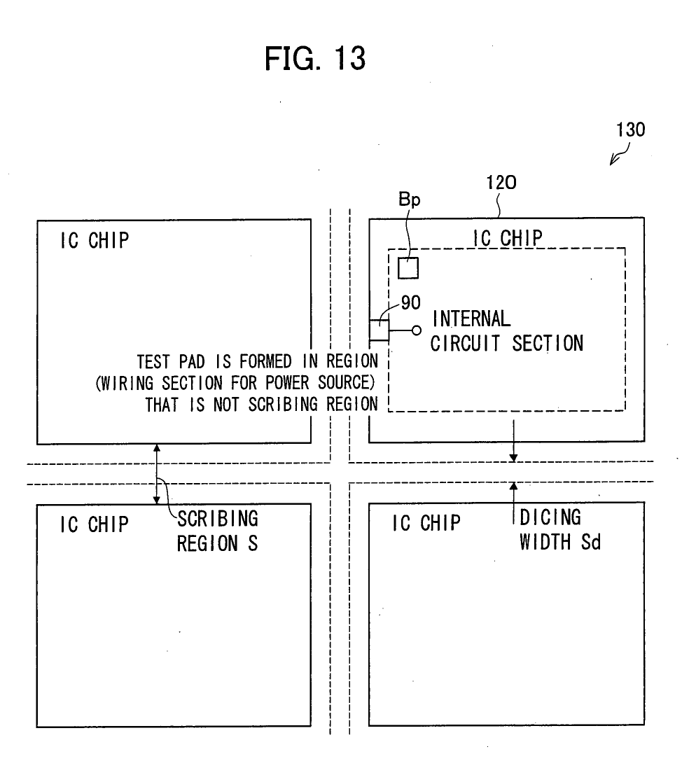

Moreover, Publicly Known Document 4 (Japanese Unexamined Patent Publication No. 343839/2002 (Tokukai 2002-343839) (published on Nov. 29, 2002)) and Publicly Known Document 5 (Japanese Unexamined Patent Publication No. 209176/2003 (Tokukai 2003-209176) (published on Jul. 25, 2003)) discloses, as a solution of the problem mentioned above, (a) a chip 120 whose test pad 90 is formed in an unused region (a wiring section for an electric source) that is not the scribing region S and (b) a semiconductor wafer 130 on which the chip 120 is formed, as illustrated in FIG. 13. In this case, however, when there is no unused region, the test pad 90 increases a chip area. This leads to a cost increase.

A semiconductor wafer of the present invention is explained in each of the embodiments above. However, (a) a semiconductor chip cut from the semiconductor wafer described in each of the embodiments, and (b) a semiconductor device using the semiconductor chip are also included in the technical scope of the present invention.

The semiconductor chip cut from the semiconductor wafer described in each of the embodiments explained above is a semiconductor chip whose operation and the like is highly reliable. This is because electrical short between the internal circuit and a substrate voltage of the semiconductor wafer after dicing does not occur, and moreover, the wafer test for the aforesaid semiconductor chip is reliably carried out. Thus, the semiconductor chip of the present invention and the semiconductor device using the semiconductor chip of the present invention are highly reliable.

The present invention is not limited to the description of the embodiments above, but may be altered by a skilled person within the scope of the claims. An embodiment based on a proper combination of technical means disclosed in different embodiments is encompassed in the technical scope of the present invention.

In addition to the configuration mentioned above, in the semiconductor wafer of the present invention, it is preferable that each of the test pads, which intervenes between the semiconductor chips adjacent to each other, is connected to a plurality of the switch circuits of each of the adjacent semiconductor chips; and for each of the semiconductor chips provided are a plurality of the switch control pads each of which is connected to a different combination of the switch circuits.

According to the configuration mentioned above, the semiconductor wafer is such that each of the test pads is connected to two or more switch circuits of each of the semiconductor chips adjacent to each other. This arrangement not only brings the effect mentioned above but also realizes reduction of test pad count. In other words, it becomes possible to increase the number of the internal circuits which a single test pad can measure. This allows more efficient use of the test pads.

Moreover, according to the configuration mentioned above, the semiconductor wafer has the semiconductor chips in which two or more switch control pads are provided for each of the semiconductor chips. The switch control pads are connected to each of the switch circuits so that one or more predetermined switch circuits are turned on among the switch circuits of each of the semiconductor chips.

This configuration is effective when the test pads are shared in a case where wire bonding pads are different in number on respective edges of the adjacent chips where the edges of the adjacent chips face each other.

To explain more specifically, conventionally, in the case as mentioned above, adjacent semiconductor chips were formed in such a manner that their circuit patterns are turned by 180 degrees with respect to each other, so that the wire bonding pads are identical in number on the respective edges of the adjacent semiconductor chips where the edges of the adjacent semiconductor chips face each other. As a result, the test pads were shared by the semiconductor chips adjacent to each other.

However, in such a case, adjacent semiconductor chips were formed in such a manner that their circuit patterns are turned by 180 degrees with respect to each other. Therefore, in picking up the semiconductor chips in an assembly process, such an arrangement requires a process for changing the orientations of the semiconductor chips so that the semiconductor chips are in the same orientation (For example, it is necessary to pick up the alternate semiconductor chips and then, rotate the semiconductor wafer so as to pick up the rest of the chips). This leads to a cost increase.

In the configuration mentioned above, as is clear from the explanation above, only one or more target switch circuits can be turned on among the switch circuits connected to the test pads. Therefore, unlike the conventional configuration, it is not necessary to form the semiconductor chips in such a manner that their circuit patterns are turned by 180 degrees. Accordingly, the problem mentioned above does not occur.

Moreover, in the semiconductor wafer of the present invention, in addition to the configuration mentioned above, it is preferable that each of the test pads, which intervenes between the semiconductor chips adjacent to each other, is connected to a plurality of the switch circuits of each of the adjacent semiconductor chips; and for each of the semiconductor chips provided are (a) a plurality of the switch control pads and (b) a selector circuit for selecting one or more switch circuits to be turned on among the switch circuits of each of the semiconductor chips, according to a combination of the signals respectively provided to the switch control pads.

According to the configuration mentioned above, the semiconductor wafer includes the plural switch control pads and the selector circuit. The selector circuit can select one or more switch circuits to be turned on among the plural switch circuits of the semiconductor chip. This makes it possible to connect more switch circuits to one test pad. Accordingly, it becomes possible to connect more switch circuits of the semiconductor chips adjacent to each other to a test pad. As a result, this arrangement not only brings the effect mentioned above but also realizes reduction of test pad count. In other words, it is possible to increase the number of the internal circuits which a single test pad can measure. This allows more efficient use of the test pads.

This configuration is also effective when the test pads are shared in a case where wire bonding pads are different in number on respective edges of the adjacent chips where the edges of the adjacent chips face each other. Moreover, the problem such as a cost increase does not occur, the cost increase caused by forming the semiconductor chips in such a manner that their circuit patterns are turned by 180 degrees.

In addition to the configuration mentioned above, the semiconductor wafer of the present embodiment is preferably such that the selector circuit and a power supply pad of the selector circuit are provided in the scribing region.

According to the configuration mentioned above, the selector circuit and the power supply pad of the selector circuit are provided in the scribing region. This eliminates the need for increase of a chip area and reduces a production cost, as well as brings the effect mentioned above. In other words, more internal circuits can be built in the semiconductor chip.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. A semiconductor wafer on which (i) a plurality of semiconductor chips are formed so as to be arranged and aligned lengthways and crosswise and (ii) test pads for use in wafer test are provided in a scribing region that is a reserved region for dicing, the semiconductor wafer comprising:
switch circuits each connecting a corresponding internal circuit formed in the semiconductor chip and the test pad; and
switch control pads, provided in the scribing region or the semiconductor chips, whose voltages are pulled up or down to a voltage that is equal to a substrate voltage of the semiconductor wafer, said switch control pads receiving signals whose voltages are different from the substrate voltage so that said switch circuits are turned on, wherein:
each of the test pads, which intervenes between the semiconductor chips adjacent to each other, is connected to at least one of said switch circuits of each of the adjacent semiconductor chips.

2. The semiconductor wafer as set forth in claim 1, wherein:
each of the test pads, which intervenes between the semiconductor chips adjacent to each other, is connected to a plurality of said switch circuits of each of the adjacent semiconductor chips; and
for each of the semiconductor chips provided are a plurality of said switch control pads each of which is connected to a different combination of said switch circuits.

3. The semiconductor wafer as set forth in claim 1, wherein:
each of the test pads, which intervenes between the semiconductor chips adjacent to each other, is connected to a plurality of said switch circuits of each of the adjacent semiconductor chips; and
for each of the semiconductor chips provided are (a) a plurality of said switch control pads and (b) a selector circuit for selecting one or more switch circuits to be turned on among said switch circuits of each of the semiconductor chips, according to a combination of the signals respectively provided to the switch control pads.

4. The semiconductor wafer as set forth in claim 3, wherein:
the selector circuit and a power supply pad of the selector circuit are provided in the scribing region.

5. A wafer testing method of a semiconductor wafer including:
a plurality of semiconductor chips formed so as to be arranged and aligned lengthways and crosswise;
test pads for use in wafer test, being provided in a scribing region that is a reserved region for dicing;
switch circuits each connecting a corresponding internal circuit formed in the semiconductor chip and the test pad; and
switch control pads, provided in the scribing region or the semiconductor chips, whose voltages are pulled up or down to a voltage that is equal to a substrate voltage of the semiconductor wafer, said switch control pads receiving signals whose voltages are different from the substrate voltage so that said switch circuits are turned on, wherein:
each of the test pads, which intervenes between the semiconductor chips adjacent to each other, is connected to at least one of said switch circuits of each of the adjacent semiconductor chips,
wherein:
a probe needle is brought into contact with at least one of the switch control pads so that at least one of the switch circuits of a semiconductor chip to be tested only is turned on among the semiconductor chips; and
a probe needle is brought into contact with the test pad so that electrical characteristics of the semiconductor chip to be tested are measured.

6. The wafer testing method as set forth in claim 5, wherein:
each of the test pads, which intervenes between the semiconductor chips adjacent to each other, is connected to a plurality of said switch circuits of each of the adjacent semiconductor chips; and
for each of the semiconductor chips provided are a plurality of said switch control pads each of which is connected to a different combination of said switch circuits.

7. The wafer testing method as set forth in claim 5, wherein:
each of the test pads, which intervenes between the semiconductor chips adjacent to each other, is connected to a plurality of said switch circuits of each of the adjacent semiconductor chips; and
for each of the semiconductor chips provided are (a) a plurality of said switch control pads and (b) a selector circuit for selecting one or more switch circuits to be turned on among said switch circuits of each of the semiconductor chips, according to a combination of the signals respectively provided to the switch control pads.

8. The wafer testing method as set forth in claim 7, wherein:
the selector circuit and a power supply pad of the selector circuit are provided in the scribing region.

9. A semiconductor chip cut from a semiconductor wafer including:
a plurality of semiconductor chips formed so as to be arranged and aligned lengthways and crosswise;
test pads for use in wafer test, being provided in a scribing region that is a reserved region for dicing;
switch circuits each connecting a corresponding internal circuit formed in the semiconductor chip and the test pad; and
switch control pads, provided in the scribing region or the semiconductor chips, whose voltages are pulled up or down to a voltage that is equal to a substrate voltage of the semiconductor wafer, said switch control pads receiving signals whose voltages are different from the substrate voltage so that said switch circuits are turned on, wherein:
each of the test pads, which intervenes between the semiconductor chips adjacent to each other, is connected to at least one of said switch circuits of each of the adjacent semiconductor chips.

10. A semiconductor device comprising a semiconductor chip cut from a semiconductor wafer including:
a plurality of semiconductor chips formed so as to be arranged and aligned lengthways and crosswise;
test pads for use in wafer test, being provided in a scribing region that is a reserved region for dicing;
switch circuits each connecting a corresponding internal circuit formed in the semiconductor chip and the test pad; and
switch control pads, provided in the scribing region or the semiconductor chips, whose voltages are pulled up or down to a voltage that is equal to a substrate voltage of the semiconductor wafer, said switch control pads receiving signals whose voltages are different from the substrate voltage so that said switch circuits are turned on, wherein:
each of the test pads, which intervenes between the semiconductor chips adjacent to each other, is connected to at least one of said switch circuits of each of the adjacent semiconductor chips.
